(19) United States
(12) Patent Application Publication
(10) Pub. No.: US 2007/0134844 A1
(43) Pub. Date: Jun. 14, 2007

(54) Process for producing flip-chip type semiconductor device and semiconductor device produced by the process

(75) Inventors: Kaoru Katoh, Usui-gun (JP); Masatoshi Asano, Usui-gun (JP); Hiroyuki Takenaka, Himeji-shi (JP); Kazuaki Sumita, Usui-gun (JP)

Correspondence Address: BIRCH STEWART KOLASCH & BIRCH, PO BOX 747, FALLS CHURCH, VA, 22040-0747, US

(73) Assignee: Shin-Etsu Chemical Co., Ltd.

(21) Appl. No.: 11/637,102

(22) Filed: Dec. 12, 2006

(30) Foreign Application Priority Data
Dec. 13, 2005 (JP) P.2005-358440

(51) Int. Cl. H01L 21/00

(52) U.S. Cl. 438/108

(57) ABSTRACT

The invention relates to a process for producing a semiconductor device in which a circuit substrate and a semiconductor chip are connected through a plurality of solder bump electrodes, said process comprising applying a non-cleaning type flux to at least a portion of a bonding pad in the circuit substrate and a semiconductor chip; applying an under-fill material to the circuit substrate or the semiconductor chip; positioning the semiconductor chip and the circuit substrate; and bonding the semiconductor chip and the circuit substrate through a thermocompression bonding, and a semiconductor device produced by the process. By using the process, since it is not necessary to add a flux component deteriorating the reliability of an under-fill material as the sealant to the under-fill material, reliability of the semiconductor device is not deteriorated. Further, since the intrusion step of thin film is not used, mounting can be conducted in a relatively short time.

### FIELD OF THE INVENTION

The present invention relates to a process for producing a flip-chip type semiconductor device in which a substrate and a semiconductor chip are bonded through bumps, and a semiconductor device produced by the process.

### BACKGROUND OF THE INVENTION

In the course of increasing the integration degree, improving the performance, and reducing the weight of semiconductor devices in the field of electronic materials, semiconductor devices adopting the flip-chip bonding system have been used extensively. In the bonding method by the flip-chip system, a silicon chip is fixed and reliability is ensured by bonding the device surface of the silicon chip and an organic substrate or ceramic substrate by using solder or the like therebetween, then an under-fill material is intruded to and cured in a narrow portion between the silicon chip and the substrate by utilizing the capillary phenomenon. Accordingly, demand for the under-fill material has also been increased mainly for stress characteristics, humidity resistance characteristic and the like. Particularly, in the flip-chip bonding, since the difference of the expansion coefficient is large such that the expansion coefficient is 3 ppm/° C. for a silicon chip and 17 ppm/° C. for an organic substrate, extremely large shear stress is generated in the solder bump portion. The stress at the solder bonding portion can be lowered by injecting and curing an under-fill material between a silicon chip and a substrate. Further, also from a standpoint of humidity resistance reliability and mechanical property, it has been demonstrated that the under-fill material is effective.

However, along with the increase in the degree of integration of semiconductor devices, the die size has been increased and it sometimes exceeds 10 mm or 20 mm for one side. The flip-chip type semiconductor device using such a large die involves a problem that no sufficient intrusion of the thin film can be obtained even when the capillary phenomenon is utilized, which results in a stop of intrusion in the midway to cause unfilling or the like. Further, while a countermeasure of decreasing the amount of the filling material has been adopted for obtaining intrusion of thin film, since it causes the decrease in the expansion coefficient, it has been pointed out that the stress on the die and the sealant increases upon solder reflowing to cause peeling at the boundary between the sealant and the die and the substrate or cracks induced to packages or the sealants.

Further, the under-fill material utilizing the capillary phenomenon needs a number of steps for the intrusion step of thin film, which causes the increase in the cost. In this regard, in Japanese Patent No. 2589239 (Patent Document 1), a method of dripping an under-fill material previously mixed with a flux upon bonding of the semiconductor and then curing the under-fill material simultaneously with solder bonding is proposed. This assembling method is effective for saving the intrusion step of thin film to result in remarkable reduction of the cost.

Under the situation described above, a liquid epoxy resin as the main component and a phthalic acid anhydride type-acid anhydride as the curing agent are generally used in the existent non-flow under-fill material. This is because the acid anhydride of the curing agent itself has a flux effect and the flux property can be enhanced by excessively adding the acid anhydride optionally by more than the equivalent amount relative to the epoxy component. However, the acid anhydride such as phthalic acid anhydride tends to absorb moisture and to increase viscosity due to moisture absorption before and during use. Further, in a case of adding excess acid anhydride, uncured acid anhydride is contained in resin curing products and the uncured products intake water easily, which promotes hydrolysis even after curing and causes volumic expansion due to moisture absorption to result in a problem of lowering the reliability, for example, in a flip-chip type semiconductor device. Further, also in a case of adding flux materials other than the acid anhydride, a great amount of addition thereof is required for enhancing the solder bondability of the non-flow under-fill materials. Accordingly, the curability is inhibited and adhesion to the substrate is deteriorated in many cases, so that no semiconductor devices capable of satisfying the reliability have yet been obtained at present.

Further, in JP-A-2005-105021 (Patent Document 2), an under-fill material incorporated with an aromatic carboxylic acid having two or more carboxyl groups is proposed. However, blending of such a carboxylic acid with a resin also involves a drawback that no sufficient flux performance is obtainable in a case that the blending amount of the carboxylic acid is insufficient, or it is less liquefied in a case that the blending amount is excessive.

Furthermore, in JP-A-5-243331 (Patent Document 3), a method of coating a flux on a substrate, further supplying a resin for sealing, and then placing a semiconductor device over the substrate is proposed. However, the proposal does not intend to supply the sealing resin in advance and an adhesive for provisional fixing is supplied to a portion except for bumps, so that a resin has to be supplied further for protecting the periphery of the bumps in the subsequent step and it does not improve the intrusion step of thin film.

Patent Document 1: Japanese Patent No. 2589239

Patent Document 2: JP-A-2005-105021

Patent Document 3: JP-A-5-243331

### SUMMARY OF THE INVENTION

The present invention has been achieved in view of the foregoing situations. According to the present invention, there is no requirement for adding a flux component which deteriorates the performance of an under-fill material as the sealant to the under-fill material. Accordingly, it is possible to provide a semiconductor device with high reliability since a resin having weak or no flux performance can be used as the under-fill material.

In view of the foregoing situations, the present inventors made intensive studies, thereby achieving the present invention.

That is, the present invention relates to the followings.
(1) A process for producing a semiconductor device in which a circuit substrate and a semiconductor chip are connected through a plurality of solder bump electrodes, said process comprising:

applying a non-cleaning type flux to at least a portion of a bonding pad in the circuit substrate and a semiconductor chip;

applying an under-fill material to the circuit substrate or the semiconductor chip;

positioning the semiconductor chip and the circuit substrate; and

bonding the semiconductor chip and the circuit substrate through a thermocompression bonding.
(2) The process for producing a semiconductor device according to (1), wherein said applying of the under-fill material is conducted by dispensing, screen printing, or stencil printing.
(3) The process for producing a semiconductor device according to (1), wherein the thermocompression bonding is conducted by pulse heating or reflowing.
(4) The process for producing a semiconductor device according to (1), wherein the under-fill material is an epoxy resin.
(5) The process for producing a semiconductor device according to (4), wherein said epoxy resin comprises an epoxy resin represented by the following formula (1):

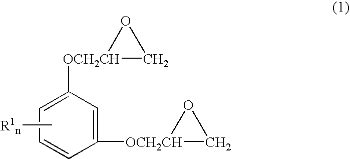

wherein R¹ represents a hydrogen atom or a monovalent hydrocarbon group having 1 to 20 carbon atoms, and n is an integer of 1 to 4, and

wherein when n is 2 or above, R¹'s are the same or different.
(6) A semiconductor device produced by the process for producing a semiconductor device according to (1).

According to the present invention, application of the under-fill material is preferably conducted by dispensing, screen printing, or stencil printing, and the thermocompression bonding after applying the under-fill material is preferably conducted by pulse heating or reflowing.

Further, the resin used in the invention is not sometimes cured in the bonding step through thermocompression bonding and, in such a case, a step of curing the resin can be achieved by additionally using a dryer after the bonding step.

According to the method of the invention, since it is not necessary to add a flux component which deteriorates the reliability of a under-fill material as a sealant to the under-fill material, the reliability of the semiconductor device is not deteriorated. Further, since the process of the present invention does not include an intrusion step of thin film, it has an advantage that mounting can be conducted in a relatively short time.

### BRIEF DESCRIPTION OF THE DRAWINGS

FIG. 1 shows a conceptional view of a flip-chip type semiconductor device.

### DESCRIPTION FOR REFERENCES

1 electronic circuit substrate
2 under-fill material
3 pad
4 semiconductor chip
5 solder bump

### DETAILED DESCRIPTION OF THE INVENTION

The present invention is to be described more specifically. The under-fill material used in the invention is, preferably, a thermosetting resin and, more preferably, one-component epoxy resin which is liquid at ordinary temperature. The epoxy resin which is liquid at ordinary temperature is not particularly restricted for the molecular structure, molecular weight, and the like so long as it has two or more epoxy groups in one molecule. Particularly, examples of the epoxy resin which is liquid at ordinary temperature include, bisphenol epoxy resins such as bisphenol A epoxy resin and bisphenol F epoxy resin; novolac epoxy resins such as phenol novolac epoxy resin and cresol novolac epoxy resin; naphthalene epoxy resins; biphenyl epoxy resins; and cyclopentadiene epoxy resins. The epoxy resins can be used each alone or in admixture of two or more of them. Among them, epoxy resins which are liquid at room temperature (for example, at 25° C.) are preferred.

An epoxy resin represented by the following structure may be added to the epoxy resin described above with no problem within a range in which undesired effects on the fluidity are given.

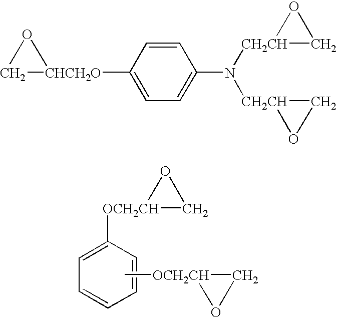

In the invention, it is particularly preferable that the epoxy resin represented by the following formula (1) is contained in the epoxy resin described above.

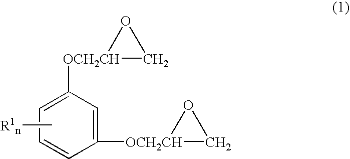

In the formula (1), R¹ represents a hydrogen atom or a monovalent hydrocarbon group having 1 to 20, preferably 1 to 10, and more preferably 1 to 3 carbon atoms. Examples of the monovalent hydrocarbon group include, alkyl groups such as methyl group, ethyl group and propyl group; and alkenyl groups such as vinyl group and allyl group. Furthermore, n is an integer of 1 to 4, and preferably 1 or 2. When n is 2 or above, R¹'s are the same or different.

The total chlorine content in the liquid epoxy resin has to be 1500 ppm or less, and preferably 1000 ppm or less. Further, chlorine extracted in water at 100° C. for 20 hours at an epoxy resin concentration of 50% is preferably 10 ppm or less. The total chlorine content exceeding 1500 ppm and the chlorine in water extracted in water exceeding 10 ppm may possibly give undesired effects on the reliability, particularly, humidity resistance of a semiconductor device.

The content of the epoxy resin represented by the formula (1) described above in the entire epoxy resin is from 25 to 100 wt %, more preferably from 50 to 100 wt %, and further preferably from 75 to 100 wt %. In a case where it is less than 25 wt %, viscosity of the composition may possibly increase or the heat resistance of the curing product may possibly be lowered. The viscosity of the epoxy resin at 25° C. is preferably 1000 Pa·s or less, and more preferably 500 Pa·s or less in view of the working property.

A curing agent is added for curing the liquid epoxy resin of the invention. The curing system for the epoxy resin is not particularly restricted and any of curing systems including a single curing system, acid anhydride curing system or amine curing system may be adopted and used arbitrarily so long as it does not hinder the gist of the invention. Examples of the curing agent include compounds having two or more functional groups capable of reacting with the epoxy groups in the liquid epoxy resin such as phenolic hydroxyl group, amino group, and acid anhydride group (one or more group in a case of the acid anhydride group). While molecular structure, molecular weight, and the like are not particularly restricted and conventional compounds can be used, the phenolic curing agent is used particularly preferably.

Specific examples of the phenol resin having at least two or more phenolic hydroxyl groups in one molecule include novolac phenol resins such as phenol novolac resin and cresol novolac resin; xylylene modified novolac resins such as para-xylylene modified novolac resin, meta-xylylene modified novolac resin, and ortho-xylylene modified novolac resin; bisphenol phenol resins such as bisphenol A resin and bisphenol F resin; biphenyl phenol resins; resole phenol resins; phenol aralkyl resins; biphenyl aralkyl resins; triphenol alkane resins such as triphenol methane resin and triphenol propane resins, and polymers thereof; naphthalene ring-containing phenol resins; and dicyclopentadiene modified phenol resins. Any of such phenol resins can be used.

Particularly, the phenolic curing agent of the invention preferably includes a phenolic curing agent represented by the following formula (2).

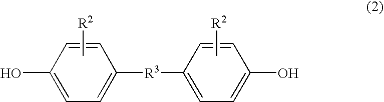

In the formula (2), R²'s are the same or different, and each independently represent a monovalent hydrocarbon group having 10 or less carbon atoms. Specific examples thereof include alkyl groups such as methyl group, ethyl group, propyl group, isopropyl group, butyl group, isobutyl group, and tert-butyl group; and alkenyl groups such as vinyl group, allyl group, propenyl group, butenyl group, and hexenyl group. Particularly, R² is preferably a monovalent hydrocarbon group having a double bond and having 10 or less carbon atoms, preferably from 2 to 10 carbon atoms, and vinyl group, allyl group, or hexenyl group are particularly preferred.

R³ is one of divalent hydrocarbon groups represented by the following formulae.

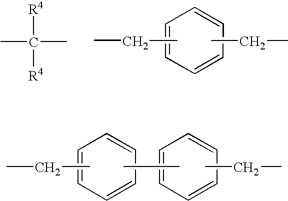

In the above formulae, R⁴'s are the same or different, and each independently represent a monovalent hydrocarbon group having 10 or less, preferably 1 to 5 carbon atoms excluding alkenyl groups. Examples thereof include alkyl groups such as methyl group, ethyl group, propyl group, isopropyl group, butyl group, isobutyl group, and tert-butyl group.

The phenolic curing agent represented by the formula (2) is preferably liquid at ordinary temperature and viscosity at 25° C. is preferably 300 Pa·s or less, and more preferably 100 Pa·s or less. In a case where the viscosity exceeds 300 Pa·s, the viscosity of the composition increases and the working property may be deteriorated.

The addition amount of the curing agent of the invention is such an effective amount to cure the epoxy resin. While it is selected arbitrarily, in a case of a phenolic curing agent, the phenolic hydroxyl groups per 1 mol of the epoxy groups contained in the liquid epoxy resin is preferably from 0.7 to 1.3 molar times, and particularly preferably from 0.8 to 1.2 molar times.

Further, in the invention, a curing promoter may be formulated for curing the liquid epoxy resin or for promoting the curing reaction between the liquid epoxy resin and the curing agent. While the curing promoter is not particularly restricted so long as it promotes the curing reaction, it is particularly preferred to use those containing one or more of cure promoting catalysts selected from imidazole compound, organic phosphorous compounds, and the like as they are, a microcapsule type curing promoter incorporating the curing promoter described above at the inside or a mixture thereof.

As the imidazole compound, those represented by the following formula (3) can be used.

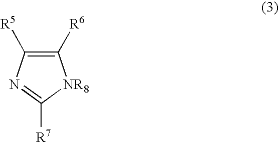

In the formula (3), R⁵ and R⁶ each independently represent one member selected from a hydrogen atom, methyl group, ethyl group, hydroxymethyl group, and phenyl group; R⁷ is a member selected from methyl group, ethyl group, pentadecyl group, undecyl group, phenyl group, and allyl group; and R⁸ is a member selected from a hydrogen atom, methyl group, ethyl group, cyanoethyl group, benzyl group, or a group represented by the following formula (4).

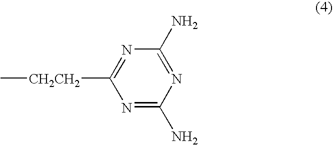

Specific examples of the imidazole compounds include 2-methyl imidazole, 2-ethyl imidazole, 1,2-dimethyl imidazole, 2,4-dimethyl imidazole, 1,2-diethyl imidazole, 2-ethyl-4-methyl imidazole, 2-heptadecyl imidazole, 2-undecyl imidazole, 2-phenyl imidazole, 1-benzyl-2-methyl imidazole, 1-benzyl-2-phenyl imidazole, 1-cyanoethyl-2-methyl imidazole, 1-cyanoethyl-2-undecyl imidazole, 2,4-diamino-6-[2′-methyl imidazolyl-(1)′]-ethyl-S-triazine, 2,4-diamino-6-[2′-ethyl-4′-methyl imidazolyl-(1)′]-ethyl-S-triazine, 2,4-diamino-6-[2′-undecyl imidazolyl]ethyl-S-triazine, 2,4-diamino-6-[2′-methyl imidazolyl (1)′]-ethyl-S-triazine isocyanulic acid adduct, 2-phenyl-4-methyl-5-hydroxymethyl imidazole, 2-phenyl-4,5-dihydroxymethyl imidazole, and 2-aryl-4,5-diphenyl imidazole.

The imidazole compounds described above can be used by being added as they are, as a microcapsule type curing promoter incorporating the compound described above at the inside, or as a mixture thereof.

On the other hand, examples of the organic phosphorous compounds include triorgano phosphine such as triphenyl phosphine, tributyl phosphine, tri(p-methylphenyl) phosphine, tri(nonylphenyl) phosphine or diphenyl tolyl phosphine; salts of triorgano phosphine and triorgano borane such as a salt of triphenyl phosphine and triphenyl borane; tetraorgano phosphonium such as tetraphenyl phosphonium; and salts of tetraorgano phosphonium and tetraorgano borate such as a salt of tetraphenyl phosphonium and tetraphenyl borate. Among them, those represented by the following formula (5) are preferred.

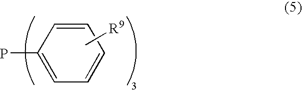

In the formula (5), R⁹'s are the same or different, and each independently represent a hydrogen atom, or an alkyl group or alkoxy group having 1 to 4 carbon atoms.

Examples of the alkyl group for R⁹ include methyl group, ethyl group, propyl group, isopropyl group, butyl group, isobutyl group, and tert-butyl group, and examples of the alkoxy group for R⁹ include methoxy group and ethoxy group. R⁹ is preferably a hydrogen atom or methyl group.

The organic phosphorous compounds described above can be used by being added as they are, as a microcapsule type curing promoter incorporating the organic phosphoric compound described above at the inside thereof or as a mixture thereof. In a case of using the organic phosphorous compound as the curing promoter as it is, it is necessary to promote the curing reaction at a melting point of solder bump or higher. Specifically, triphenyl phosphine having good balance between the curability and the latent property is preferred.

The curing promoter of the invention is preferably a microcapsule having an average particle size of from 0.5 to 10 μm, which incorporates the curing promoter described above in the inside, that is, a microcapsule type curing promoter.

Examples of the microcapsule type curing promoter include those incorporating the curing promoter (cure promoting catalyst) such as the imidazole compounds and the organic phosphorous compounds described above in the polymers of various monomers such as (meth)acrylic monomers, which are alkyl esters of 1 to 8 carbon atoms including acrylic acid ester, itaconic acid ester, and crotonic acid ester; those in which hydrogen atoms on the alkyl group in the alkyl ester are partially or entirely substituted for ally group and the like; mono-functional monomers such as styrene, α-methylstyrene, acrylonitrile, methacrylonitrile and vinyl acetate; and polyfunctional monomers such as ethylene glycol (meth)acrylate, polyethylene glycol di(meth)acrylate, divinyl benzene, bisphenol A di(meth)acrylate, and methylene bis(meth)acryl amide. As the polymer, polymers of the (meth)acrylate monomers are particularly preferred.

Examples of the process for producing the microcapsule type curing promoters of the invention include various methods and they can be produced by conventional methods. For producing a microcapsule type curing promoter with high productivity and sphericality, a suspension polymerization method or emulsion polymerization method is usually used preferably. For example, JP-A-5-247179 discloses a method of microencapsulating a solid core substance comprising, for example, amines for use in the epoxy resin curing agent as the main ingredient with a radical polymerizable monomer containing an organic acid having a polymerizable double bond.

In this case, in view of the molecular structure of the cure promoting catalyst used generally, for obtaining a microcapsule type curing promoter at a high concentration, the total amount of the monomer described above to be used is preferably from 10 to 200 weight parts, more preferably from 10 to 100 weight parts, and further preferably from 20 to 50 weight parts, based on 10 weight parts of the cure promoting catalyst. In a case where the amount is less than 10 weight parts, it is sometimes difficult that the microcapsule sufficiently contributes to the latent property of the cure promoting catalyst. In a case where the amount exceeds 200 weight parts, since the ratio of the catalyst is lowered and a great amount has to be used in order to obtain a sufficient curability, it sometimes results in an economical disadvantage. Namely, the curing promoter contained in the microcapsule can be used at a concentration of from about 5 to 50 wt %, and preferably from about 10 to 50 wt %.

Examples of the shell composition of the microcapsule type curing promoter include epoxy resin, urethane resin, polyester resin, methacrylate resin, olefin resin, and styrene resin. They may be used optionally after crosslinking.

The average grain size of the microcapsule type curing promoter is preferably of from 0.5 to 10 μm. Especially, those having an average grain size of from 0.5 to 10 μm and the maximum grain size of 50 μm or less is preferably used, and more preferably, those having an average grain size of from 2 to 5 μm and the maximum grain size of 20 μm or less is used. In a case where the average grain size is less than 0.5 μm, the specific surface area is increased to thereby possibly increase the viscosity upon mixing. In a case where it exceeds 10 μm, dispersibility with the resin becomes inhomogeneous to thereby possibly lower the reliability.

As the blending amount of the curing promoter, the blending amount in a case of using the imidazole compound, the organic phosphorous compound or the like as it is without microcapsulation is preferably from 0.1 to 15 weight parts, and particularly preferably from 0.5 to 7 weight parts based on 100 weight parts of the liquid epoxy resin. In a case where the blending amount is less than 0.1 weight parts, the curability may possibly be lowered. In a case where it exceeds 15 weight parts, while the curability is excellent, the storability may possibly be lowered.

Further, for the blending amount of the microcapsule type curing promoter, the amount of the cure promoting catalyst incorporated in the microcapsule is preferably from 1 to 15 weight parts, and particularly preferably from 2 to 10 weight parts, based on 100 weight parts of the liquid epoxy resin. In a case where the amount is less than 1 weight part, the curability may possibly be lowered. In a case where the amount exceeds 15 weight parts, while the curability is excellent, the storability of the composition may possibly be lowered.

Further, the microcapsule type curing promoter and the curing promoter described above which is not microencapsulated may be used in combination. In this case, the total of the cure promoting catalyst incorporated in the microcapsule and the curing promoter which is not microencapsulated is preferably from 1 to 15 weight parts, and particularly preferably from 2 to 7 weight parts, based on 100 weight parts of the liquid epoxy resin. In a case where the amount is less than 1 weight part, the curability may possible be lowered. In a case where the amount exceeds 15 weight parts, while the curability is excellent, the storability of the composition may possibly be lowered.

In the invention, for the purpose of decreasing the expansion coefficient, various inorganic fillers conventionally used may be added. Specific examples to be used as the inorganic filler according to the invention include molten silica, crystalline silica, alumina, boron nitride, aluminum nitride, silicon nitride, magnesia, magnesium silicate and aluminum. Among them, spherical molten silica is preferred since the viscosity can be lowered.

The blending amount of the inorganic filler is preferably within a range of from 50 to 400 weight parts, and more preferably from 100 to 250 weight parts, based on the total 100 weight parts of the liquid epoxy resin and the curing agent. In a case where the amount is less than 50 weight parts, the expansion coefficient is large to thereby possibly induce occurrence of cracks in a cold heat test. In a case where the amount exceeds 400 weight parts, the viscosity is increased to thereby possibly lower the intrusion property of the thin film. The viscosity at 25° C. in this case is preferably 250 Pa·s or less, and more preferably 100 Pa·s or less.

In the epoxy resin composition of the invention, silicone rubber, silicone oil, liquid polybutadiene rubber, a thermoplastic resin comprising methyl methacrylate-butadiene-styrene may also be blended for the purpose of lowering the stress. Further, in the liquid epoxy resin composition of the invention, carbon functional silane for improving adhesion, pigment such as carbon black, dye, antioxidant, surface treating agent (γ-glycidoxy propyl trimethoxy silane, etc.) and other additives can be blended optionally.

Further, the molding method and the molding conditions for the liquid epoxy resin composition of the invention may adopt an ordinary method under solder reflowing conditions upon surface mounting. General examples include a temperature profile including starting at normal temperature, changing and keeping the temperature to 200 to 260° C. (within solder melting temperature) for one min or more and 5 min or less, and subsequent changing the temperature to normal temperature. When the temperature is not more than the solder melting temperature, solder may not possibly be bonded. When the temperature is not less than the solder melting temperature, a semiconductor device may possibly be failed due to thermal impact at high temperature. In a case where the state of the reflowing maximum temperature is less than one min, the liquid epoxy resin composition is not cured sufficiently and no sufficient adhesion strength can be attained to thereby possibly result in failure, for example, in a dropping test. In a case where the state of the reflowing maximum temperature is 5 min or more, the semiconductor device may possibly be failed due to thermal impact at high temperature.

The viscosity of the liquid epoxy resin composition used as a sealant is preferably 1,000 Pa·s or less, and particularly preferably 500 Pa·s or less at 25° C. Further, while ordinary methods can be adopted for the molding method and the molding conditions of the composition, the composition is preferably cured by heat-oven under the conditions at first at 100 to 120° C. for 0.5 hours or more, and subsequently at 150 to 175° C. for 0.5 hours or more. In a case where heating at 100 to 120° C. is conducted for less than 0.5 hours, voids are sometimes formed after curing. In a case where heating at 150 to 175° C. is conducted for less than 0.5 hours, sufficient characteristics of curing products cannot sometimes be obtained. In this case, the cure time is arbitrarily selected in accordance with the heating temperature.

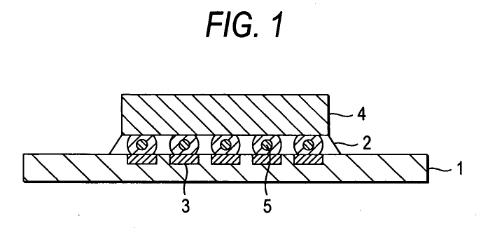

In a flip-chip type semiconductor device used in the invention, as shown in the FIG. 1, a semiconductor chip 4 is usually mounted through a plurality of solder bumps 5 over a wiring pattern surface of an electronic circuit substrate 1, and an under-fill material 2 is filled in a gap between the electronic circuit substrate 1 and the semiconductor chip 4 (gap between the bumps 5).

According to the invention, the process for producing a semiconductor device, in which the electronic circuit substrate 1 and the semiconductor chip 4 are connected through a plurality of solder bump electrodes 5, includes (1) a step of applying a non-cleaning type flux to at least a portion of bonding pads in the circuit substrate and a semiconductor chip, (2) a step of applying an under-fill material to the circuit substrate or the semiconductor chip, (3) a step of positioning the semiconductor chip and the circuit substrate, and (4) a step of bonding the semiconductor chip and the circuit substrate through a thermocompression bonding.

In this case, the flux is preferably a non-cleaning type flux, and a rosin such as abietic acid may be also used by diluting with a solvent. Further, it is preferred to evaporate a solvent ingredient contained in the flux by using a drier or the like after applying the flux for preventing occurrence of voids.

In this case, a commercially available flux may be used as it is or only the effective ingredient may be added. The effective ingredient is classified generally into a base resin and an activator. The examples of the base resin include abietic acid, dehydroabietic acid, dihydroabietic acid, tetrahydroabietic acid, neoabietic acid, isopimaric acid, pimaric acid, levopimaric acid and parastric acid. The examples of the activator include benzoic acid, stearic acid, lactic acid, citric acid, oxalic acid, succinic acid, adipic acid and sebacic acid.

The applying amount of the flux is, as the coating amount after drying, preferably from 0.05 to 2 weight parts, and particularly preferably from 0.05 to 0.5 weight parts based on 100 weight parts of the entire resin. In a case where the flux is less than 0.05 weight parts, no sufficient effect thereof can be obtained. Further, in a case where the flux is more than 2 weight parts, a great amount of flux remains at the periphery of the solder bumps and. In this case, since the flux has a larger heat expansion coefficient relative to the solder bump and it has lower protection property for the solder bumps in comparison with the under-fill material, preferable results cannot be obtained.

Further, application of the under-fill material is preferably conducted by dispensing, screen printing or stencil printing, and the dispensing method is particularly preferred in view of the cost.

A method of bonding the semiconductor chip and the circuit substrate through thermocompression bonding is preferably conducted by pulse heating or reflowing, and the pulse heating is particularly preferred.

### EXAMPLE

The present invention is to be described specifically with reference to examples and comparative example, but the invention is not restricted to the following examples.

JTEG Phase 2E175 of lead-free type of a flip-chip kit having 576 pieces of solder bumps mounted thereon, manufactured by Hitachi Super LSI Systems Co. was used as a semiconductor chip and JKIT TYPE-III manufactured by the company was used as a substrate. The semiconductor chip and the substrate constitute a daisy chain by the bonding of both of them and can be in electronic conduction in a case where all the soldering bumps in the chip can be bonded. Namely, even one of the 576 pieces of bumps cannot be bonded, it shows an insulating property in a conduction test and the bonding is difficult unless a mounting method with preferred bonding property is used.

Resin compositions were obtained by uniformly kneading the ingredients shown in Table 1 for the under-fill material to be used by three rolls. As a flux, abietic acid and ethanol mixed at a ratio of 20 g to 80 g was used. Using the resin compositions (hereinafter simply referred to as resins) and the flux, the following mounting test was conducted. Numerical values in Table 1 show weight parts.

The flux was applied on the solder bumps of the semiconductor chip and then dried by a drier until the solvent component was evaporated. Further, the resin described above was applied on the substrate paired therewith by using an auto-dispenser. Those after applied with the steps described above were used for Example 1 and 2.

### Example 1

The semiconductor chip and the substrate after the step described above were positioned and crimped by using a flip-chip bonder having a pulse heating function and then thermocompression bonding was conducted by pulse heating. After the thermocompression bonding, the resin was cured at 150° C. for 2 hours using a drier.

### Example 2

The semiconductor chip and the substrate after the step were positioned and crimped by using a flip-chip bonder, and solder of the crimped sample was melted in a reflowing furnace to bond the semiconductor chip and the substrate. Then, resin was cured at 150° C. for 2 hours using a drier.

### Comparative Example 1

A semiconductor chip in which a flux is not applied to the solder bump portion, and a substrate applied with the resin as in the example were positioned, crimped, and bonded through thermocompression bonding by using a flip-chip bonder provided with a pulse heater as in Example 1. Namely, this is in accordance with the process of Example 1 except that the flux is not applied.

### Comparative Example 2

A semiconductor chip through the same step as in Comparative Example 1 and a substrate were positioned and crimped by a flip-chip bonder in the same manner as in Example 2 to prepare a sample, and solder was melted in a reflowing furnace to bond the semiconductor chip and the substrate. Then, the resin was cured at 150° C. for 2 hours using a drier. As in Comparative Example 1, this is in accordance with the process of Example 2 except that the flux is not applied.

### Comparative Example 3

Bonding was conducted in the same method as in Comparative Example 1 by using the resin composition of Table 1 with further addition of 20 mass parts of methyl tetrahydro phthalic acid anhydride as a curing agent (MH700 manufactured by New Japan Chemical Co., Ltd.) for enhancing the flux property.

Conduction Test

Conduction tests were conducted by measuring resistance between terminals of samples manufactured by Example 1 and 2 and Comparative Examples 1 to 3. The values in the conduction test show the resistance values (ohm) of daisy chains.

PCT Test

Samples manufactured in Examples 1 and 2 and Comparative Examples 1 to 3 were put under a PCT circumstance (Pressure Cooker Test: 121° C., 2.1 atm) and peeling after 168 hours was confirmed by C-SAM.

TABLE 1

| Composition ingredient | | | | Comp. | Comp. | Comp. |
|---|---|---|---|---|---|---|
| (weight parts) | | Example 1 | Example 2 | Example 1 | Example 2 | Example 3 |
| Epoxy resin | | 53.0 | 53.0 | 53.0 | 53.0 | 53.0 |
| Curing agent | | 47.0 | 47.0 | 47.0 | 47.0 | 67.0 |
| Inorganic filler | | 150.0 | 150 | 150.0 | 150 | 150 |
| Curing promoter a | | 0.2 | 0.2 | 0.2 | 0.2 | 0.2 |
| Curing promoter b | | 2.0 | 2.0 | 2.0 | 2.0 | 2.0 |
| production | Applying | YES | YES | NO | NO | NO |
| steps | Flux | | | | | |
| | Solder | Thermocompression | Furnace | Thermocompression | Furnace | Thermocompression |
| | melting | Bonding | melting | Bonding | melting | Bonding |
| | bonding | | | | | |
| Evaluation | Conduction | 20.1 | 20.2 | Not conducted | Not | 19.9 |
| tests | test | | | | conducted | |
| | PCT test | A | A | A | A | B |

Results of PCT test
A: Good
B: Bad

Epoxy Resin

Bisphenol F epoxy resin: RE303S-L (manufactured by Nippon Kayaku Co., Ltd.)

Curing Agent

Methyl tetrahydro phthalic acid anhydride: MH700 (manufactured by Shin-Nippon Rika Co.)

Inorganic Filler

Spherical silica: SE8FC (maximum grain size: 24 μm or less, average grain size: 6 μm, manufactured by Tokuyama Soda Co., Ltd.)

Curing Promoter

Curing promoter a: Cresole C₁₁Z-PW (manufactured by Shikoku Chemicals Corp.)

Curing promotor b: Microcapsule of 2E4MZ, methyl methacrylate polymer containing 20 wt % of 2E4MZ (manufactured by Shikoku Chemicals Corp.). Average particle size thereof is 7 μm. The amount of catalyst leached from the microcapsule by a treatment in o-cresol at 30° C. for 15 min is 87 wt %.

While good conduction was obtained in Examples 1 and 2, conduction was not obtained in Comparative Examples 1 and 2. In Comparative Example 3, it was confirmed that while initial bonding was good, peeling occurred during the PCT test and the resin reliability was lowered. While the flux was applied on the side of the semiconductor chip in the experiment described above, it may be applied on the side of the substrate. Further, while the under-fill material was applied by dispensing, a printing method may also be adopted without involving any problem.

While the present invention has been described in detail and with reference to specific embodiments thereof, it will be apparent to one skilled in the art that various changes and modifications can be made therein without departing from the scope thereof.

This application is based on Japanese patent application No. 2005-358440 filed Dec. 13, 2005, the entire contents thereof being hereby incorporated by reference.

Further, all references cited herein are incorporated in their entireties.

What is claimed is:

1. A process for producing a semiconductor device in which a circuit substrate and a semiconductor chip are connected through a plurality of solder bump electrodes, said process comprising:
applying a non-cleaning type flux to at least a portion of a bonding pad in the circuit substrate and a semiconductor chip;
applying an under-fill material to the circuit substrate or the semiconductor chip;
positioning the semiconductor chip and the circuit substrate; and
bonding the semiconductor chip and the circuit substrate through a thermocompression bonding.

2. The process for producing a semiconductor device according to claim 1, wherein said applying of the under-fill material is conducted by dispensing, screen printing, or stencil printing.

3. The process for producing a semiconductor device according to claim 1, wherein the thermocompression bonding is conducted by pulse heating or reflowing.

4. The process for producing a semiconductor device according to claim 1, wherein the under-fill material is an epoxy resin.

5. The process for producing a semiconductor device according to claim 4, wherein said epoxy resin comprises an epoxy resin represented by the following formula (1): 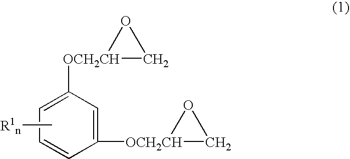
wherein R¹ represents a hydrogen atom or a monovalent hydrocarbon group having 1 to 20 carbon atoms, and n is an integer of 1 to 4, and
wherein when n is 2 or above, R¹'s are the same or different.

6. A semiconductor device produced by the process for producing a semiconductor device according to claim 1.
